(19) United States
(12) Patent Application Publication
(10) Pub. No.: US 2010/0097738 A1
(43) Pub. Date: Apr. 22, 2010

(54) ELECTROSTATIC CHUCK AND SUBSTRATE BONDING DEVICE USING THE SAME

(75) Inventors: Pil-Joong KANG, Jinju-si (KR); Jae-Woo Joung, Suwon-si (KR); Suk-Ho Song, Ansan-si (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD.

(21) Appl. No.: 12/413,005

(22) Filed: Mar. 27, 2009

(30) Foreign Application Priority Data
Oct. 20, 2008 (KR) 10-2008-0102527

(51) Int. Cl. H01L 21/683

(52) U.S. Cl. 361/234

(57) ABSTRACT

An electrostatic chuck and a substrate bonding device equipped with the electrostatic chuck are disclosed. The electrostatic chuck in accordance with an embodiment of the present invention includes: an elastic holder, in which a center portion of one surface of the elastic holder is formed in a convex shape; an electrode, which is coupled to the elastic holder such that the elastic holder is electrically charged; and a holding unit, which holds the other surface of the elastic holder. The electrostatic chuck in accordance with an embodiment of the present invention can prevent a defect caused by a void formed between substrates while bonding the substrates.

### CROSS-REFERENCE TO RELATED APPLICATIONS

This application claims the benefit of Korean Patent Application No. 10-2008-0102527, filed with the Korean Intellectual Property Office on Oct. 20, 2008, the disclosure of which is incorporated herein by reference in its entirety.

### BACKGROUND

1. Technical Field

The present invention relates to an electrostatic chuck and a substrate bonding device equipped with the electrostatic chuck.

2. Description of the Related Art

A variety of wafer bonding technologies are applied to a semiconductor manufacturing process. Such technologies include silicon direct bonding, anodic bonding, eutectic bonding, glass frit and adhesive (polymer) bonding.

Such wafer bonding processes can be mainly divided into two steps. Firstly, two wafers are aligned with each other, and then the two wafers are pre-bonded to each other. In the case of silicon direct bonding, the pre-bonded wafers are coupled to each other by way of OH bonding, or a center portion is only in contact, and an edge is fixed mechanically. In the case of anodic bonding, the two wafers are only aligned mechanically. Then, energy, such as heat, force and voltage, required for bonding the wafers is supplied to bond them.

FIG. 1 is a cross-sectional view showing a wafer bonding device in accordance with the related art. The wafer bonding device holds a first wafer and a second wafer by using a vacuum holder at a first jig and a second jig, respectively. Then, the first wafer and the second wafer are aligned with each other and bonded together by applying pressure on them.

In a wafer manufacturing process, however, a surface of the wafer may be damaged, or the wafer may be partially bent. FIG. 2 is an infrared image showing a wafer bonded in accordance with the related art. When performing the bonding using the wafer, a void between the wafers may be generated during the pre-bonding process, and thus, as illustrated in FIG. 2, perfect bonding between the wafers can be difficult to achieve.

### SUMMARY

The present invention provides a substrate bonding device that can prevent a void from being formed between substrates, such as wafers, when bonding the substrates.

An aspect of the present invention provides an electrostatic chuck. The electrostatic chuck in accordance with an embodiment of the present invention includes: an elastic holder, in which a center portion of one surface of the elastic holder is formed in a convex shape; an electrode, which is coupled to the elastic holder such that the elastic holder is electrically charged; and a holding unit, which holds the other surface of the elastic holder.

Here, the electrostatic chuck can further include a pressure controller, which controls the pressure of the elastic holder. Fluid is filled in the elastic holder, and the pressure controller can control the pressure of the fluid. The holding unit can hold an edge of the elastic holder such that a center portion of the elastic holder is convexly protruded.

Another aspect of the invention provides a device for bonding substrates. The device for bonding substrates, in which the device bonds a first substrate and a second substrate, in accordance with an embodiment of the present invention includes: a jig, which supports the first substrate; an electrostatic chuck, which holds the second substrate such that the second substrate faces the first substrate; and a pressing unit, which presses the electrostatic chuck toward the jig, in which the electrostatic chuck includes: an elastic holder, in which a center portion of one surface of the elastic holder is formed in a convex shape such that a center portion of the second substrate is convexly protruded; an electrode, which is coupled to the elastic holder such that the elastic holder is electrically charged; and a holding unit, which holds the other surface of the elastic holder.

Here, the electrostatic chuck can further include a pressure controller, which controls the pressure of the elastic holder. Fluid is filled in the elastic holder, and the pressure controller can control the pressure of the fluid. The holding unit can hold an edge of the elastic holder such that a center portion of the elastic holder is convexly protruded.

The device for bonding substrates can further include a suction unit, which adheres the first substrate to the jig.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view showing a wafer bonding device in accordance with the related art.

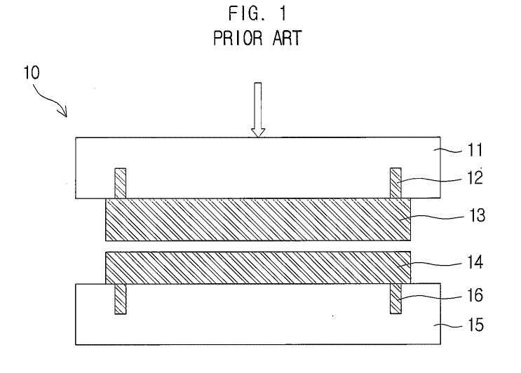

FIG. 2 is an infrared image showing a wafer bonded in accordance with the related art.

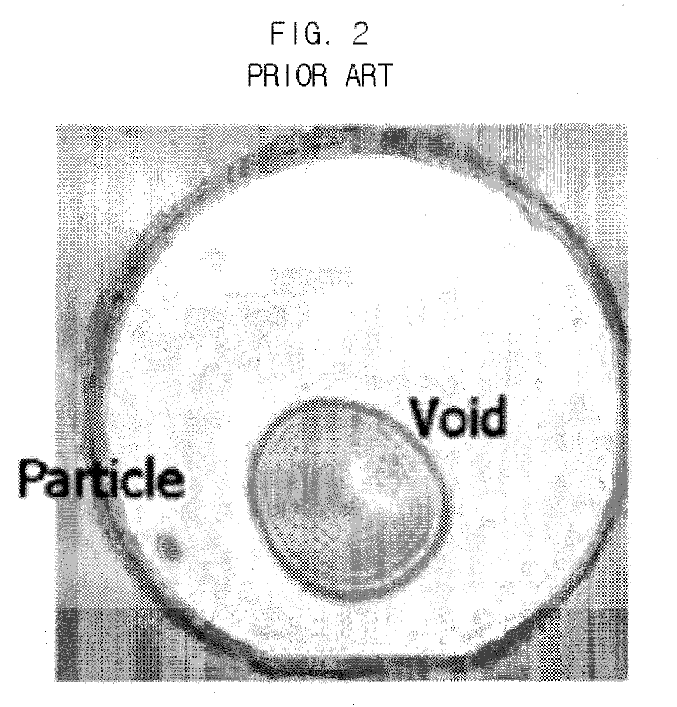

FIG. 3 is a cross-sectional view showing a wafer bonding device in accordance with an embodiment of the present invention.

FIG. 4 is a cross-sectional view showing an electrostatic chuck in accordance with an embodiment of the present invention.

FIG. 5 is a perspective view showing an elastic holder in accordance with an embodiment of the present invention.

FIG. 6 is a cross-sectional view showing a process of bonding a wafer in accordance with an embodiment of the present invention.

FIG. 7 is a cross-sectional view showing a wafer bonding device in accordance with another embodiment of the present invention.

FIG. 8 is a cross-sectional view showing an electrostatic chuck in accordance with another embodiment of the present invention.

### DETAILED DESCRIPTION

The features and advantages of this invention will become apparent through the below drawings and description.

A wafer bonding device according to certain embodiments of the present invention will be described below in more detail with reference to the accompanying drawings. Those components that are the same or are in correspondence are rendered the same reference numeral regardless of the figure number, and redundant descriptions are omitted.

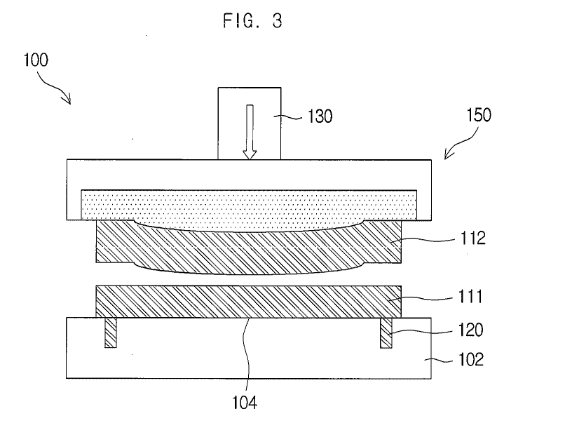

FIG. 3 is a cross-sectional view showing a wafer bonding device 100 in accordance with an embodiment of the present invention. As illustrated in FIG. 3, the wafer bonding device 100 in accordance with an embodiment of the present invention includes a jig 102, which supports a first wafer 111, an electrostatic chuck 150, which holds a second wafer 112 such that the second wafer 112 faces the first wafer 111, and a pressing unit 130, which presses the electrostatic chuck 150 toward the jig 102. Here, the electrostatic chuck 150 includes an elastic holder 152, which has a convexly curved surface at the center such that a center portion of the second wafer 112 is formed in a convex shape, an electrode 156, which is coupled to the elastic holder 152 such that the elastic holder 152 is electrically charged, and a holding unit 154, which holds the other surface of the elastic holder 152. Therefore, the wafer bonding device 100 in accordance with an embodiment of the present invention can prevent a void from being formed between the wafers bonded.

The wafer bonding device 100, which is a device for bonding the first wafer 111 and the second wafer 112 together, can align the first and second wafers with each other and then press them together. Here, it shall be obvious that a device, which supplies heat, pressure and/or voltage to the first and second wafers 111 and 112, can be added to the wafer bonding device 100, depending on the method of bonding the wafer. Although the present embodiment describes the wafer bonding as an example, any material other than the wafer, for example, a substrate, can be also bonded.

The jig 102 can support the first wafer 111 by mounting the first wafer 111 on its supporting surface 104. By coupling a suction unit 120 to the jig 102, the first wafer 111 can be adhered to the jig 102. The suction unit 120 can hold the first wafer 111 on the jig 102 by forming a vacuum space between the jig 102 and the first wafer 111, thereby facilitating the alignment of the first wafer 111 and the second wafer 112 more easily.

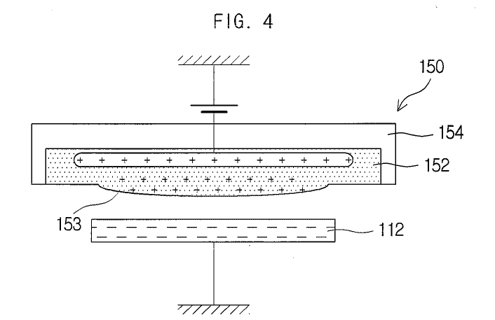

FIG. 4 is a cross-sectional view showing the electrostatic chuck 150 in accordance with an embodiment of the present invention. The electrostatic chuck 150 can include an elastic holder 152, an electrode 156 and a holding unit 154, as illustrated in FIG. 4. The electrostatic chuck 150 can hold the second wafer 112 such that the second wafer 112 faces the first wafer 111. Here, the electrostatic chuck 150 can hold the second wafer 112 by the gravitation generated between the electrostatic chuck 150 and the second wafer 112 by charging the second wafer 112.

The electrode 156 is coupled inside the elastic holder 152. A device for supplying voltage can be coupled to the electrode 156. When the voltage is supplied to the electrode 156, the elastic holder 152 is electrically charged. Therefore, the electrostatic chuck 150 can hold the second wafer 112 by the electrostatic gravitation.

The holding unit 154 can he made of a rigid material such as stainless steel. The holding unit 154 can hold the other surface of the elastic holder 152 such that the elastic holder 152 faces the jig 102.

The pressing unit 130, which is coupled to the holding unit 154, can press the electrostatic chuck 150 toward the jig 102. The pressing unit 130 can include an actuator, such as a hydraulic cylinder or a pneumatic cylinder, which is capable of linear movement.

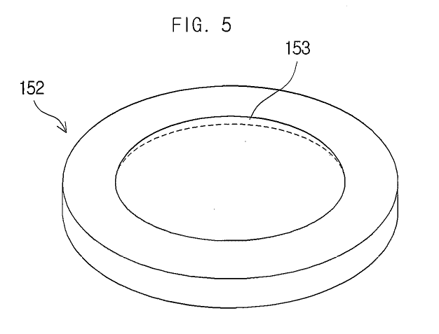

FIG. 5 is a perspective view showing the elastic holder 152 in accordance with an embodiment of the present invention. The elastic holder 152 has a holding surface 153 for holding the second wafer 112, as illustrated in FIG. 5. The holding surface 153 is formed on one surface of the elastic holder 152 and formed in a convex shape at the center. In other words, the holding surface 153, on which the second wafer 112 is being held by the electrostatic gravitation, is formed such that the center portion is convexly curved, like a portion of a sphere. The elastic holder 152 can be made of a material, such as a rubber, which can be elastically deformed.

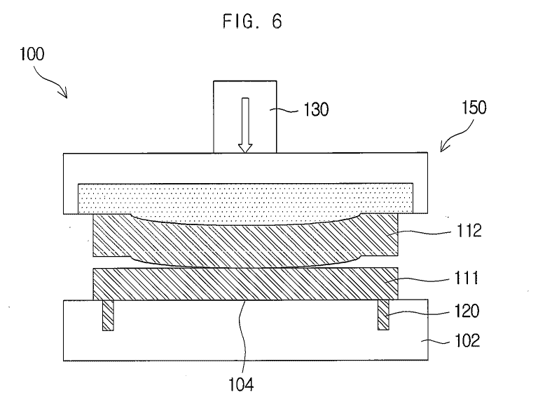

FIG. 6 is a cross-sectional view showing a process of bonding a wafer in accordance with an embodiment of the present invention. The second wafer 112, which is held by the elastic holder 152, is held through an entire surface of the elastic holder 152 by the electrostatic gravitation. Therefore, the center portion of the second wafer 112 can be convexly curved in accordance with the shape of the surface of the elastic holder 152.

When the second wafer 112 is pressed toward the first wafer 111 by the pressing unit 130, the center portion of the second wafer 112 is in point-contact with the first wafer 111. Since the elastic holder 152 is made of an elastic material, when the pressing unit 130 presses the second wafer 112 toward the first wafer 111, a convexly curved area of a center portion of the elastic holder 152 is elastically deformed, and thus a contact surface between the first wafer 111 and the second wafer 112 can be extended from the center to the edge. Therefore, air interposed between the first wafer 111 and the second wafer 112 moves toward the outside, thereby preventing a void from being formed between them.

Even if there is a defect, such as a partial damage or warpage, on a surface of the second wafer 112, the second wafer 112 can be held by the elastic holder 152 along the holding surface 153 because a center portion of the holding surface 153 of the elastic holder 152 is convexly curved. Therefore, the elastic holder 152 formed in such a shape can prevent a void from being generated during the bonding of the first wafer 111 and the second wafer 112.

When the first wafer 111 and the second wafer 112 are in full-contact, the bonding between the first wafer 111 and the second wafer 112 can be completed by applying voltage, heat and/or pressure, depending on the method of bonding the first wafer 111 and the second wafer 112.

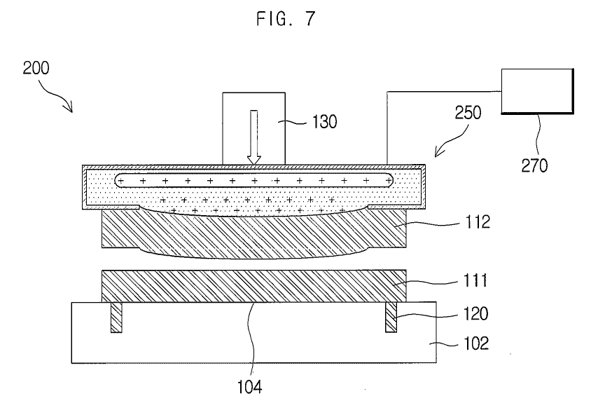

FIG. 7 is a cross-sectional view showing a wafer bonding device 200 in accordance with another embodiment of the present invention. As illustrated in FIG. 7, by further including a pressure controller 270 for controlling the pressure of an elastic holder 252, the wafer bonding device 200 in accordance with another embodiment of the present invention can make a center portion of the elastic holder 252 convexly protruded when the elastic holder 252 holds the second wafer 112. Likewise, when the second wafer 112 and the first wafer 111 are in contact, the second wafer 112 can be contacted with the first wafer 111 from the center to the edge by gradually sinking the center portion of the elastic holder 252.

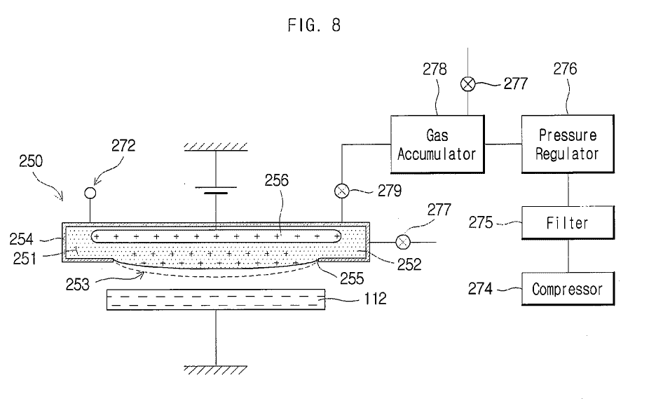

FIG. 8 is a cross-sectional view showing an electrostatic chuck 250 in accordance with another embodiment of the present invention. A chamber 251 for forming a hollow space is formed inside the elastic holder 252 such that gas can be filled in the hollow space, as illustrated in FIG. 8. Liquid in a gas-like form can be filled in the chamber 251 to control the pressure inside the chamber 251. A holding surface 253 of the elastic holder 252 can be protruded or sunk, depending on the pressure inside the elastic holder 252.

A holding unit 254 can be made of a rigid material such as stainless steel, and an opening 255 can be formed on one surface of the holding unit 254. Therefore, when the pressure inside the elastic holder 252 increases, the holding unit 254 can control the expansion of the elastic holder 252 other than the holding surface 253 of the elastic holder 252 such that the holding surface 253 is convexly protruded.

A pressure controller 270 can control the protrusion of the holding surface 253 by controlling the pressure of the gas being filled in the elastic holder 252. The pressure controller 270 can include a compressor 274, a pressure regulator 276, a gas accumulator 278 and relief valves 277 and 277′.

The compressor 274 increases the pressure of the gas filled in the elastic holder 252 by reducing its volume, and then the gas accumulator 278 is filled with the compressed gas through a filter 275 and the pressure regulator 276. The pressure of the pressure regulator 276 is properly controlled by the relief valve 277. The gas inside the pressure regulator 276 is filled in the chamber 251 through an one-way valve 279. The pressure of the chamber 251 can be controlled by the relief valve 277′. A pressure gauge 272 can be coupled to one side of the chamber 251, allowing the pressure gauge 272 to detect the pressure.

The pressure controller 270 in accordance with the configuration described above can fill the gas in the chamber 251 when the second wafer 112 is held by the holding surface 253. When the chamber 251 is filled with the gas, the elastic holder 252, in which the expansion of the elastic holder 252 other than the holding surface 253 is controlled by the holding unit 254, allows the holding surface 253 to be convexly protruded. Therefore, the second wafer 112 is held by the elastic holder 252, while the center portion of the second wafer 112 is convexly curved in accordance with the shape of the holding surface 253.

Next, when the second wafer 112 is pressed toward the first wafer 111 by the pressing unit 130, the center portion of the second wafer 112 is in point-contact with the first wafer 111. When the pressing unit 130 presses the second wafer 112 toward the first wafer 111, the second wafer 112 is contacted with the first wafer 111 while the contact area is spreading out in all directions from the center to the edge.

Here, the pressure controller 270 gradually decreases the pressure in the chamber 251 such that a center portion of the holding surface 253 is slowly sunk, thus preventing a void between the second wafer 112 and the first wafer 111 from being formed.

As such, the pressure controller 270 can control the angle and magnitude of contact between the second wafer 112 and the first wafer 111 when the second wafer 112 is initially contacted with the first wafer 111, by controlling how much the holding surface 253 of the elastic holder 252 is convexly protruded.

While the spirit of the invention has been described in detail with reference to particular embodiments, the embodiments are for illustrative purposes only and shall not limit the invention. It is to be appreciated that those skilled in the art can change or modify the embodiments without departing from the scope and spirit of the invention. As such, many embodiments other than those set forth above can he found in the appended claims.

What is claimed is:

1. An electrostatic chuck comprising:
an elastic holder, a center portion of one surface of the elastic holder being formed in a convex shape;
an electrode being coupled to the elastic holder such that the elastic holder is electrically charged; and
a holding unit configured to hold the other surface of the elastic holder.

2. The electrostatic chuck of claim 1, further comprising a pressure controller configured to control the pressure of the elastic holder.

3. The electrostatic chuck of claim 2, wherein:
fluid is filled in the elastic holder; and
the pressure controller controls the pressure of the fluid.

4. The electrostatic chuck of claim 2, wherein the holding unit is configured to hold an edge of the elastic holder such that a center portion of the elastic holder is convexly protruded.

5. A device for bonding substrates, comprising:
a jig configured to support a first substrate;
an electrostatic chuck configured to hold a second substrate such that the second substrate faces the first substrate; and
a pressing unit configured to press the electrostatic chuck toward the jig,
wherein the electrostatic chuck comprises:
an elastic holder, a center portion of one surface of the elastic holder being formed in a convex shape such that a center portion of the second substrate is convexly protruded;
an electrode coupled to the elastic holder such that the elastic holder is electrically charged; and
a holding unit configured to hold the other surface of the elastic holder.

6. The device of claim 5, further comprising a pressure controller configured to control the pressure of the elastic holder.

7. The device of claim 6, wherein:
fluid is filled in the elastic holder; and
the pressure controller controls the pressure of the fluid.

8. The device of claim 6, wherein the holding unit is configured to hold an edge of the elastic bolder such that a center portion of the elastic holder is convexly protruded.

9. The device of claim 5, further comprising a suction unit configured to adhere the first substrate to the jig.
